(19) United States
(12) Patent Application Publication
(10) Pub. No.: US 2013/0104983 A1
(43) Pub. Date: May 2, 2013

(54) Selective Reflector for Enhanced Solar Cell Efficiency

(71) Applicant: The Regents of the University of California, Oakland, CA (US)

(72) Inventors: Ze'ev R. Abrams, Alameda, CA (US); Avi Niv, Kfar-Blum (IL); Majid Gharghi, Berkeley, CA (US); Xiang Zhang, Alamo, CA (US)

(73) Assignee: The Regents of the University of California, Oakland, CA (US)

(21) Appl. No.: 13/665,380

(22) Filed: Oct. 31, 2012

Related U.S. Application Data
(60) Provisional application No. 61/553,788, filed on Oct. 31, 2011.

(51) Int. Cl. H01L 31/0232; H01L 31/18

(52) U.S. Cl. 136/259; 438/72; 257/E31.127

(57) ABSTRACT

This invention improves the efficiency of non-optimal solar cell materials, enabling them to achieve the same efficiency as optimal materials. The invention describes a method of improving the emission and absorption properties of a generic photovoltaic cell using feedback reflectors and/or filters, increasing the open circuit voltage of the cell, and thus the overall efficiency. Specific examples of single junction photovoltaics are detailed, but not limited to. Particularly, semiconducting solar cells in either single- or multi-junction formats are described. The invention can be applied to any functioning solar cell to increase the efficiency, while describing the maximal efficiency available using thermodynamic identities. Other examples are included, such as organic photovoltaic, nanostractured photovoltaic devices, and non-planar geometries. The invention thus enables using non-optimal photovoltaic materials to achieve similar efficiency results as optimal ones, regardless of the designed structure or material used.

### CROSS REFERENCE TO RELATED APPLICATIONS

This application claims priority to U.S. Provisional Application Ser. No. 61/553,788 filed Oct. 31, 2011, which application is incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-AC02-05CH11231 between the U.S. Department of Energy and the Regents of the University of California for the management and operation of the Lawrence Berkeley National Laboratory. The government has certain rights in this invention.

### BACKGROUND OF THE INVENTION

1. Field of the Invention

The present invention deals with solar cells, specifically photovoltaic systems (PVS) based on inorganic (semiconducting) and/or organic materials, whereby the solar radiation is absorbed by a material, and power is extracted directly from the device. The invention describes enhanced efficiency of the power extracted from the PVS via the spectral control of the solar radiation. It can be applied to any new or existing solar cell design, ranging from household PVS to industrial level solar power plants. The invention describes a photon flux capture method that essentially captures and scavenges the re-emitted photons from the cell, and then feeds it back into the PVS in a feedback loop. The material systems that the invention claims to improve are described, where less-than-optimal PVS materials, which may have formerly been neglected due to their less-than-optimal capabilities, can be improved to match the highest grade materials, while fulfilling the basic fundamental limits imposed by the 2^{nd} law of thermodynamics.

2. Brief Description of the Related Art

Solar energy is free and renewable, and is increasingly becoming an obvious choice of energy for our future needs. Extracting power from the solar radiation can be done in multiple forms, each with their own benefits and drawbacks. One of the primary methods of utilizing the solar radiation flux is by directly producing power using a photovoltaic system. These systems are becoming more ubiquitous and economical, as advances in methods of making cheaper and better materials for photovoltaic conversion are found, as well as reducing the overall cost of the systems. However, by finding ways to improve the efficiency of a PVS, this cost can be reduced as well, leading to an abundance of research in the world, searching for ways of improving the efficiency of existing material systems.

Solar energy from the cell can be absorbed and utilized through a variety of means, with different degrees of efficiencies. In particular, using PVS, the solar radiation can be directly converted into electric power via the utilization of an electronic bandgap material. Limitations imposed by the fundamental laws of thermodynamics restrict the maximal efficiency attainable from the solar radiation, which would optimally act as a heat transfer engine between the sun, a hot blackbody at ˜6000 degrees K, and the earth, a ˜300 K blackbody, when the two are at thermal equilibrium with each other. The maximal efficiency of extracting work from such a temperature is known as the Carnot efficiency, and denoted as η_{C}=(1−Tₒ/T_{S}), where Tₒand T_{S} denote the ambient temperature (terrestrial, or extra-terrestrial for satellite operation), respectively.

A PVS maximizes its efficiency by attempting to absorb as much light as possible, in order to convert each photon from the solar flux into electrons, which can then be extracted for use as electricity. In an inorganic semiconducting systems, this is realized using a bandgap structure; in an organic or polymeric system, this is realized using any two-level system such as those defined by highest occupied molecular orbital (HOMO) and lowest occupied molecular orbital (LUMO) bands. In these PVS, the generation of an electron will create a complementary electronic hole pair in the material, separated energetically by a bandgap of forbidden energy levels, such that the energetic difference between the population of electrons and holes is characterized by the chemical potential difference between population energy levels, and directly relates to the extractable voltage from the PVS. However, due to this bandgap of energy levels, photons from the solar radiation cannot be absorbed if they have energy less than the bandgap. This interplay between the amount of absorbable light from the solar radiation spectrum, as limited by the bandgap from below, as opposed to the maximal voltage extractable from the PVS, as limited by the bandgap from above, lies at the heart of traditional PVS efficiency calculations, since the ultimate power to be extracted from the PVS is related to the multiplication of the absorbed photon flux with the voltage.

However, in addition to maximizing the absorption into the solar cell, there is an additional requirement for achieving maximal efficiency from a PVS, known as the detailed-balance limit, first proposed by Shockley & Queisser in 1961. This limit views the solar cell from the concept of detailed balance, which is derived from the general principals of thermodynamics. The detailed balance hypothesis claims that in an optimal, lossless system, the total flux of photons irradiating the PVS must be balanced by concurrent flux of emission out of the material. For a PVS system, this emission is a balance of the thermal blackbody radiation due to its temperature at Tₒ, as well as the emission of recombining electron-hole pairs, which in an optimal PVS material, would produce a single photon per recombining pair, For the injection of photons from the sun, this latter form of emission surpasses the former by ˜5 orders of magnitude, such that the former channel can be ignored for most theoretical efficiency calculations.

The detailed balance limit thus provides the maximal voltage obtainable for a solar cell, using the basic laws of thermodynamics, for a lossless material system. Any additional losses lower this maximal efficiency, however does not change the fundamental physical processes of the system. For example, the Shockley-Queisser detailed balance calculation was done for a single bandgap semiconducting PVS, and maximized the efficiency as a function of bandgap of the PVS, obtaining a maximal efficiency of ˜31% for an optimal bandgap of ˜1.3 eV. In theory, by stacking multiple materials with rising bandgaps, the absorption of the solar radiation can be optimized to the solar spectrum, with efficiencies approaching the Carnot limit under maximal concentration operation.

A useful way to view the maximal efficiency of single bandgap/junction PVS is to focus on the most important factors in determining the efficiency, assuming that the solar spectrum is kept constant over time (terrestrial, extra-terrestrial, or even pure blackbody). These two factors are the short-circuit current and the open-circuit voltage. The short-circuit current is directly proportionate to the absorption under the ultimate efficiency hypothesis defined by Shockley & Quiesser, wherein every incoming photon is absorbed and creates an electron-hole pair. The current is directly related to the incoming photon flux (N) by a multiplication by the elementary electron charge, q. for a PVS with a single bandgap, the absorption term is simply blackbody radiation emitted from the sun, following Planck's law, multiplied by the solid-angle beam extending from the sun onto a solar cell, Q_{S}, with area, A. The simplest approximation of the absorption coefficient (α) of the material with a bandgap of E_{gap} is a step function (Heaviside function, u), which is zero for all values of photons with energy of E below the bandgap energy (E=hω relating the energy to the frequency, ω, by a multiplication by Planck's reduced constant, h), and unity for all photons above with energy above the bandgap:

$$α ( ω ) = \{ \begin{matrix}0 & ℏω < {E}_{gap} \\ 1 & ℏω \geq {E}_{gap}\end{matrix} \} ≡ u ( {E}_{gap} ) \qquad ( 1 )$$

This approximation holds for ideal materials, particularly for highly absorbing ones with direct bandgaps (meaning that they can absorb photons without associated changes in momentum of the crystal lattice). By using Eq. (1) in Planck's blackbody formula, we obtain the input solar current into the solar cell, for a traditional single bandgap material:

$${I}_{in}^{Sun} = q {\dot{N}}_{in}^{Sun} = \frac{2 q {Ω}_{S} C}{{h}^{3} {c}^{2}} {\int }_{{E}_{gap}}^{∞} \frac{{E}^{2} d E}{{e}^{E / {kT}_{S}} - 1} \qquad ( 2 )$$

where the integral's lower limit is at E_{gap} due to the absorption coefficient. The factor C denotes the concentration of sunlight, which can be achieved using lenses or other geometrical means.

When no current is extracted from the PVS, we can view it as a bandgap-limited blackbody (by ignoring the smaller thermal blackbody radiation), and the emission from such a material follows a modified version of Planck's law:

$${I}_{out}^{BB} = q {\dot{N}}_{out}^{BB} = \frac{8 π {qn}^{2}}{{h}^{3} {c}^{2}} {\int }_{{E}_{gap}}^{∞} \frac{{E}^{2} d E}{{e}^{( E - μ ) / {kT}_{o}} - 1} \qquad ( 3 )$$

Where the difference between Eq. (3) and Eq. (2) is the addition of the chemical potential, μ, and the change in temperature to Tₒ, as well as changing the outgoing emission from a small solid angle of the sun, Ω_{S}=6.85×10⁻⁵ sr, to a full isotropic emission, at 4π sr. The index of the PVS material, n, can be taken as unity, without any loss of generality.

To calculate the maximal efficiency of a PVS, using the detailed balance formulism, we must balance the emission and absorption, while multiplied by the voltage extracted (V), since the power is given by:

$$η = \frac{{P}_{out}}{{P}_{in}} = \frac{A \times [ {I}_{in}^{Sun} - {I}_{out}^{BB} ( V ) ] \times V}{A \times {I}_{in}^{Sun}} \qquad ( 4 )$$

Note that the area of the cell, A, cancels out, leaving the current and voltage as being the free variables of the system, which can be independently optimized.

The current term in Eq. (4) is a function of the voltage, since the outgoing emission is a function of the chemical potential, which is related to the voltage (at open-circuit conditions) by: μ=qV. The maximal current is easy to find by setting V=0:

I^{max}=I_{sc}=Iᵢₙ^{Sun}−Iₒᵤₜ^{BB}(0) (5)

In contrast, the maximal voltage obtainable does not go to infinity, since there are thermodynamic limits to this voltage using the fundamental thermodynamic relation of the Gibbs free energy, G:

G=μ=U−T×S (6)

Where U is the energy of the system, T is the temperature (Tₒ), and S is the entropy. Since the energy is limited by the photons and the bandgap, this voltage has traditionally been considered to be limited to the bandgap. This relation can be found by isolating the open-circuit voltage, which is by definition the highest obtainable voltage in any PVS circuit, by finding the maximum of Eq. (4) as a function of V, and using the relation of Eq. (6). To do this, we note that at open-circuit conditions, due to the necessary equation of flux due to the detailed balance hypothesis, as well as Kirchhoff's law of radiation, Eq. (2) must equal Eq. (3). By using an approximation of the integrals, whereupon E>>kT_{S}, and E−μ>>kTₒ, we can ignore the −1 in the denominators, and analytically solve the integrals to find a closed-form relation for the open-circuit voltage, V_{oc}:

$${μ}_{oc}^{reg} = {qV}_{oc}^{reg} = {E}_{gap} {η}_{C} - {kT}_{o} ln [ ( \frac{{Ω}_{S} C}{4 π {n}^{2}} ) ( \frac{{T}_{S}}{{T}_{o}} ) {a}_{1} ] \qquad ( 7 )$$

Where η_{C} is the Carnot efficiency, as described above, and the α₁ term is a small correction term from the integral:

α₁=1+2kT_{S}/E_{gap}+2(kT_{S}/E_{gap})² (8)

This term is small for most bandgaps.

Viewing Eq. (7), we can recognize its relation to Eq. (6), by noting that the bracketed terms are manifestations of the entropy, and that the energy term, U, can be associated with the term E_{gap}η_{C}. This association leads to the conclusion that the maximal obtainable voltage by a PVS is limited by the bandgap and the Carnot efficiency. In fact, the original Shockley-Queisser paper limited the open-circuit voltage to be no more than E_{gap}.

Embodiments of the invention described here defeat this limit by describing that the emission from the PVS can be tailored such that the maximum is shifted, without violating the 2^{nd} law of thermodynamics.

An additionally useful way to look at the efficiency calculation using the detailed balance formalism is to realize that all the useful information regarding the efficiency of Eq. (4) can be found by relating the input and output currents into the PVS. By using the formalism of Transfer Functions, we can denote a transfer function, H(V), as:

$$H ( V ) ≡ \frac{{I}_{out}}{{I}_{in}} = ( 1 - \frac{{I}_{out}^{BB}}{{I}_{in}} ) \qquad ( 9 )$$

as depicted as Iᵢₙ^{sun} 1, transfer function, H(V) 2 and 4, and Iₒᵤₜ 3 of FIG. 1. This transfer function holds all the useful information of a PVS material that follows an emission rate as Eq. (3), and is nonlinear. The input current in the denominator of Eq. (9) is taken in the detailed balance formalism of Shockley & Queisser as Eq. (2). By solving the transfer function for H(V)=0, which is the open circuit condition, we can find the maximal voltage obtainable, as given by Eq. (7).

The detailed balance limit for a regular solar cell is depicted by the curve in 6 of FIG. 1, with the maximum efficiency per bandgap of the underlying PVS, as found by Eq. (4), and using only the equations presented here for the solar radiation (instead of the AM1.5 terrestrial radiation). This approach was chosen to retain generality, as well as emphasize the salient features of the system under analysis from a physical perspective. Furthermore, the index of the material and the concentration were taken as unity (n=1; C=1). The maximum at ˜30% can be improved when taking terrestrial values of the solar radiation, which blocks some wavelengths, and raises the efficiency to ˜33%. However, this does not change the generality of the method described, and is only a numerical variation.

The maximum of the efficiency curve is not at zero due to the multiplication by the voltage, which is highly related and dependent upon the bandgap of the PVS, as signified by Eq. (7). This value is not dependent upon the materials used, but only on the single junction bandgap, and two level system model described, using the formalism described above. The curve 6 in FIG. 1 thus provides the maximally obtainable efficiency considering any PVS, assuming no concentration. All actual efficiency curves will be lower than this curve, unless concentration is added. Even with concentration, the efficiency curve cannot surpass the Ultimate Efficiency, which can be found by taking Tₒ=0 K, a mostly unrealistic consideration. The maximal efficiency for the Ultimate Efficiency is 44%, for a bandgap of ˜1.1 eV.

As described, it has been universally acknowledged that any result surpassing this detailed balance limit must be in direct violation of the 2^{nd} law of thermodynamics, and thus physically impossible. However, there are methods of exceeding this limit without violating any physical laws. These methods rely on violating the conditions for the detailed balance formulation as posited by Shockley & Quiesser. In particular, by choosing multiple bandgap materials, in a method known as tandem, or multi-junction cells, one can increase the efficiency of a PVS by better matching the bandgap absorption properties to the impinging solar spectrum. In theory, by taking infinite slabs of varying bandgap materials one can obtain in excess of 85% efficiency of solar energy conversion. However, such a PVS has many material limitations that cause such a device to be extremely expensive, and therefore not applicable to widespread use. Nevertheless, their increased efficiency, particularly at high optical concentration, makes them useful for extra-terrestrial and power plant applications.

Another way of exceeding the Shockley-Queisser limit is to create material systems that challenge the Ultimate Efficiency hypothesis, wherein every incoming photon creates a single electron-hole pair. By finding materials where such symmetries are broken—while complying with the conservation of energy—the current of a PVS can be increased. Similarly, by manipulating the incoming solar spectrum, one can modify the denominator of Eq. (9) and therefore increase the efficiency, as is done in some spectral splitting techniques. These techniques are examples of what are known today as 3^{rd} generation techniques, whereby the 31% Shockley-Queisser limit (with no concentration) is surpassed, while retaining a single junction bandgap of the underlying PVS.

While the 3^{rd} generation methods attempt to modify the Ultimate Efficiency hypothesis, the general assumption has always been that the detailed balance formalism is written in stone for any single junction bandgap PVS. Embodiments of the invention show how to surpass this limitation in a simple way that may not have been thought of before.

### SUMMARY OF THE INVENTION

Embodiments of the invention are based on controlling the output emission of the PVS, so as to maximize the overall efficiency. To do so, feedback is utilized to decrease the amount of lost energy due to re-emitted photons.

To understand the mechanism of the process, we first describe the case for a regular solar cell design, operating at maximal efficiency configuration. The schematic diagram 8 depicted in FIG. 2, displays a single bandgap PVS, here signified by a two level system, that can be associated with a semiconductor/inorganic or other organic/polymeric material system. The incoming photons 9 follow the general solar spectrum of a blackbody radiator at temperature T_{S}, and are absorbed by the PVS from the bandgap E_{gap} and upward, as described in Eq. (1), with a unit step function absorption coefficient at the bandgap. These photons 9 can produce electron-hole pairs 13 above the bandgap E_{gap}, with all residual energy lost to thermalization to the bandgap. At open-circuit conditions, the outgoing emission must match the incoming emission flux (Kirchhoff's law of radiation and detailed balance), such that the emission rate near the chemical potential is maximized. These photons 15 are the result of band-to-band recombination of the electron hole pairs 14. This emission is maximized for a material system without any losses, such that all the recombination 14 is radiative 15. Losses such as, but not limited to, Shockley-Read-Hall recombination via mid-gap traps, or Auger recombination via energy exchange will limit the emission rate in a negative manner, and thus lower the maximal voltage obtainable by the cell. The buildup of electrons at the bandgap provides the potential that can be utilized in an external circuit using a PVS.

Since this emission out of the PVS is critical for building up the internal potential of the system, the primary embodiment of our device relies on a reabsorbing the blackbody emission that arises from band-to-band recombination. As shown by an emission profile curve 17 in FIG. 2, this emission profile 17 appears as a one sided spike centered on the chemical potential μ_{oc}, which is just below the bandgap E_{gap}, as approximated by Eq. (7). By placing a selective reflector or reflective filter (35 of FIG. 3), this emission out of the PVS can be selectively reabsorbed by the material. By reflecting the solar flux near the bandgap E_{gap}, the absorption of the PVS falls a small amount, since the absorption is typically from the bandgap E_{gap} and upward (in terms of energy, or frequency). However, by providing feedback of the re-emitted photons 15 using the selective reflector 35, the open-circuit voltage will rise, above the limit set in Eq. (7).

Evaluating the current-voltage relationship for this cell can he done by employing the same transfer function method described above. For a selective reflector 35 consisting of either a High Pass Filter (HPF, passes all energy above a threshold), which is also called a Short. Pass Filter in optics, or a Notch Filter (NF, prevents a certain bandwidth of energies from passing), or a Band Pass Filter (BPF, or, depending on the notation, a Band Stop Filter), we can generalize by stating that the filter will indirectly affect the absorption coefficient of the device:

$${α}^{FC} ( ω ) = \{ \begin{matrix}0 & ℏω < {E}_{gap} + {Δ}_{gap} \\ 1 & ℏω \geq {E}_{gap} + {Δ}_{gap}\end{matrix} \} ≡ u ( {E}_{gap} + {Δ}_{gap} ) \qquad ( 10 )$$

where the added energy blocked by the filter/reflector (selective reflector 35) is denoted by Δ_{gap}, being a selective reflector shift, and the absorption coefficient of the device is denoted as α^{FC}. Since the input flux is modified, the relation of Eq. (2) is changed to include this absorption coefficient. Furthermore, the bandgap emitted photons are re-fed into the device, however only from the bandgap E_{gap} until the reflector width Δ_{gap}. Using the transfer function system design, we can summarize the invention in the block diagram 27 of FIG. 3, with the feedback loop utilizing a selective HPF 31, however, without losing generality, a BPF or NF can be used instead, as described in detail below.

Using the transfer function design, we can evaluate the open-circuit condition by solving for H(V)=0, as in the regular case, while retaining the transfer function of the regular solar cell, as denoted in Eq. (9); we can write the detailed balance in this case as:

$${Ω}_{S} C {\int }_{{E}_{gap} + {Δ}_{gap}}^{∞} \frac{{E}^{2} d E}{{e}^{E / {kT}_{S}} - 1} + 4 π {n}^{2} {\int }_{{E}_{gap}}^{{E}_{gap} + {Δ}_{gap}} \frac{{E}^{2} d E}{{e}^{( E - qV ) / {kT}_{o}} - 1} = 4 π {n}^{2} {\int }_{{E}_{gap}}^{∞} \frac{{E}^{2} d E}{{e}^{( E - qV ) / {kT}_{o}} - 1} \qquad ( 11 )$$

with the notation used as above. The first term is the truncated solar flux; the second is the feedback re-emission, and the last term is the regular emission from the blackbody of the PVS.

Equation 11 is one primary result of our invention, incorporating both the selective filter/reflector (selective reflector 35), as well as the feedback mechanism, feeding the emitted current back into the PVS. By recombining the second and third term, this equation can be re-written as:

$${Ω}_{S} C {\int }_{{E}_{gap} + {Δ}_{gap}}^{∞} \frac{{E}^{2} d E}{{e}^{E / {kT}_{S}} - 1} = 4 π {n}^{2} {\int }_{{E}_{gap} + {Δ}_{gap}}^{∞} \frac{{E}^{2} d E}{{e}^{( E - qV ) / {kT}_{o}} - 1} \qquad ( 12 )$$

This equation can be approximated for the open-circuit voltage, under the same conditions as used in Eq. (7):

qV_{oc}^{FC}≅(E_{gap}+Δ_{gap})η_{C}−kTₒ ln [(Ω_{S}C/4πn²)(T_{S}/Tₒ)α_{Δ}] (13)

Eq. (13) is similar in form to Eq. (7) with the following modifications: The energy term (U) is modified to include a selective reflector 35, such that the open-circuit voltage is increased. In addition, the small correction term, α_{Δ} is included, and is:

α_{Δ}=α₁+2Δ_{gap}/E_{gap}+(Δ_{gap}/E_{gap})²+2kT_{S}Δ_{gap}/E_{gap}² (14)

Where α₁ is taken from Eq. (8).

The major difference between a regular cell, using the traditional detailed balance formalism, and the selective reflector cell, using feedback, is the rise in the open-circuit voltage, as can be summarized as:

V_{oc}^{reg}∝E_{gap}η_{C}

V_{oc}^{FC}∝(E_{gap}+Δ_{gap})η_{C} (15)

with the reduction of current due to the selective reflector width negligible for small widths, Δ_{gap}.

An embodiment of the invention is thus summarized in FIG. 3, in both the system design, employing a feedback loop 30 with a selective reflector 31, as well as in the schematic of FIG. 3, generalizing for a generic single junction PVS. In this schematic, the added selective reflector 31 traps the emission from the blackbody PVS within the overall device, such that the voltage utilizable by the PVS is the summation of the bandgap created voltage, as well as the voltage on the selective reflector 31, 35, which raises the electron population's energy to above the bandgap. The expected efficiency increase per bandgap, and per selective reflector width is displayed in FIG. 4, under the assumptions described above, using a two level system approximation of a single junction bandgap PVS.

The effect described is similar to that of the Burstein-Moss effect in semiconductors, where the effective absorption edge [Eq. (1)] of small bandgap semiconductors is increased in energy due to degenerate doping, or other methods of carrier concentration increase such as current injection. The generation of carriers by the solar flux feedback increases the Fermi level of the PVS such that the population of electrons can be extracted at a higher level. The selective reflector feedback device described here is nevertheless different from the traditional Burstein-Moss effect since the absorption edge of the PVS will not change, as it does in degenerate semiconductors. In this sense, the selective reflector method is similar to a thermophotovoltaic system, where the PVS is acting as it own thermal source, via the feedback loop. This description of an embodiment of the invention, using this terminology, may therefore be referred to as an auto-thermophotovoltaic device.

The spectral modification of embodiments of the invention is not to be confused with other methods of improving the efficiency of PVS using index-matching or internal reflection techniques. In those designs, the efficiency of optimal photovoltaic materials is improved up to the detailed balance efficiency, which they would otherwise not attain, due to entropic losses. In that set of designs, the efficiency increase is only for materials up to their assumed maximal efficiency using the detailed balance formalism. In contrast, in our invention, materials that were thought to be able to attain lower maximal efficiencies using the standard detailed balance formalism can be improved beyond that maximum—while never exceeding the maximal detailed balance limit of ˜30% (which would otherwise violate the 2^{nd} law of thermodynamics). As an example of this distinction: Germanium, with a ˜0.7 eV bandgap, is calculated as having no more than ˜21% maximal efficiency due to its non-optimal absorption bandgap in relation to the solar flux. However, using embodiments of the invention, the efficiency of a Germanium based device can be improved up to ˜30%, by re-absorbing the photons within the selective reflector gap. Furthermore, it is not to be confused with photo-recycling, which internally re-absorbs the photons, and cannot raise the efficiency of the solar cell material beyond the Shockley-Queisser limit.

In embodiments of the device, the selective reflector 31, 35 can be placed completely around the device, or only on the surface that faces the solar flux. This includes the top, side and back of the PVS. In general, this includes PVS that track the sun, as well as concentrated flux systems. Furthermore, the invention is not tied to a particular geometry, and can be used for uni-facial, bi-facial, cylindrical, spherical and any other geometry device. Moreover, it can be implemented in newly devised nano- and micro-structured materials, where the geometry of the underlying PVS can be three dimensional.

In an additional embodiment of the device, the selective reflector 31, 35 can be embedded within an existing multi-junction cell. This insertion can be used to increase the efficiency of any of the layers (of the multiple bandgap materials), however, it is particularly well-suited to increase the efficiency of the top and bottom layers (simultaneously, but with different selective reflectors). In these embodiments, the selective reflectors 31, 35 can be placed either in between a stacked multi-junction layer, or on adjacent PVS materials in a horizontally designed cell. The “horizontal” design includes any cylindrical or spherical geometry, where the term “horizontal” refers to the direction of stacking either perpendicularly or in parallel to the axis (when taken in reference to the normal of the solar irradiation), depending on the coordinate system used.

In another embodiment of the device, the PVS material consists of organic or polymeric layers. In such an embodiment, the absorption and emission of the PVS may not follow the spectral properties of Eq. (11), however the general attribution of the two level systems can be used to describe such a system, and therefore the expected increase in efficiency still applies. In these embodiments, a NF/BPF may be more suitable to block the discreet levels of the system (HOMO/LUMO), as opposed to a broadband HPF. In all other respects, the organic/polymeric PVS follows the exact same characteristics of the inorganic ones, and therefore these embodiments are essentially the same as the primary embodiments.

In various embodiments of the device, the selective reflector 31, 35 may consist of, but not limited to, Photonic Crystals, Dielectric Mirrors, Bragg Reflectors (Distributed Bragg Reflectors DBR included), interference filters, mirrors, metamaterials reflectors, Frequency Tuned Diffractive Gratings, Plasmonic reflectors, and Transformation Optics.

Photonic Crystals can be tuned to block (reflect) a specific frequency. Dielectric Mirrors comprise layers of different materials used to reflect bandwidth specific light. These mirrors/materials can include dielectrics, metals, or a combination of both.

MetaMaterial reflectors comprise materials which combine combinations of materials in an architecture that changes the optical properties of the material. Specifically, it can change the dielectric constant of a “material”, using the “effective medium approximation”. These types of materials can include nano-scaled materials incorporated into a dielectric/metal composite, and have been shown to be more reflective than metals.

Frequency Tuned Diffractive Gratings can be used to create highly reflective, tunable mirrors, and are used for creating the mirrors in cavities used for lasers. Plasmonic reflectors utilize Plasmonic effects that can be integrated into many of the previous technologies, and thus is really a modification of them.

Transformation Optics is a field that is similar to MetaMaterials, where the optical properties of a material are controlled using nano/micro-structuring. In particular, light can be reflected, curved, or even cloaked using these concepts. These concepts also work in the visible light range.

The blocking of all photons with energies less than E_{gap}+Δ_{gap}, can be implemented using HPFs, NFs, BPFs/BSFs, as well as a combination of filters, mirrors and reflectors. Various embodiments could make use of blocking the solar spectrum below the bandgap of the material since these photons do not contribute to the voltage of the cell, but only to detrimental heating of the device due to interband absorption of electrons/holes above and below the bandgap. Therefore, an embodiment of the device may consist of a selective reflector 31, 35 with the property that it is a HPF(E_{gap}+Δ_{gap}). However, the gains described in this invention were calculated assuming a NF centered near the bandgap, such that the selective reflector is NF(E_{gap}→E_{gap}+Δ_{gap}), where the → symbol signifies the start and stop energies (frequencies) of the bandwidth of the NF. As such, there may or may not be a measureable difference in performance between these two embodiments using the formalism described in this patent.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 describes the traditional detailed balance formulation of the efficiency using transfer functions. The transfer function of a single junction PVS is depicted, as well as its systems diagram analogy. The efficiency curve per bandgap is also depicted, showing the maximum at ˜30% for a ˜1.3 eV bandgap material (with no concentration).

FIG. 2 depicts the schematic of the energy diagrams of both a regular PVS, with both the input and output spectral ranges inset above the photons; as well as that of the described selective reflector device. The selective reflector consists of reflectors that both reduce the impinging photon flux above the bandgap, as well as reflect the PVS blackbody emission at the bandgap back into the device, thus increasing the useable potential.

FIG. 3 depicts the schematic of the invention, in terms of system diagrams, as a feedback loop consisting of a selective frequency filter; as well as a schematic of a PVS consisting of a planar semiconductor solar cell, covered by a selective filter. The selective filter re-captures the emitted flux, and therefore adds to the voltage of the cell similar to a charged capacitor.

FIG. 4 displays the calculated efficiency results of the selective reflector system as described in the Summary section. The efficiency is plotted for different bandgaps of the underlying PVS, as well as different widths of the selective filter. The maximum efficiency from the traditional detailed balance limit (bottom row) is shifted to lower bandgaps due to the increase in voltage imparted by the selective reflector.

FIG. 5 Schematic of a multi-junction cell employing the selective reflector within the layers. The selective reflector can be included for each layer, or only for the top/bottom layer, where it will be most effective.

FIG. 6 Schematic of the selective reflector in non-planar designs, including cylindrical and spherical cells, and a horizontally stacked multi-junction cell.

FIG. 7 Diagram of the frequency/wave length response needed of the selective reflectors.

### DETAILED DESCRIPTION

In the discussions that follow, various process steps may or may not be described using certain types of manufacturing equipment, along with certain process parameters. It is to be appreciated that other types of equipment can be used, with different process parameters employed, and that some of the steps may be performed in other manufacturing equipment without departing from the scope of this invention. Furthermore, different process parameters or manufacturing equipment could be substituted for those described herein without departing from the scope of the invention.

These and other details and advantages of the present invention will become more fully apparent from the following description taken in conjunction with the accompanying drawings.

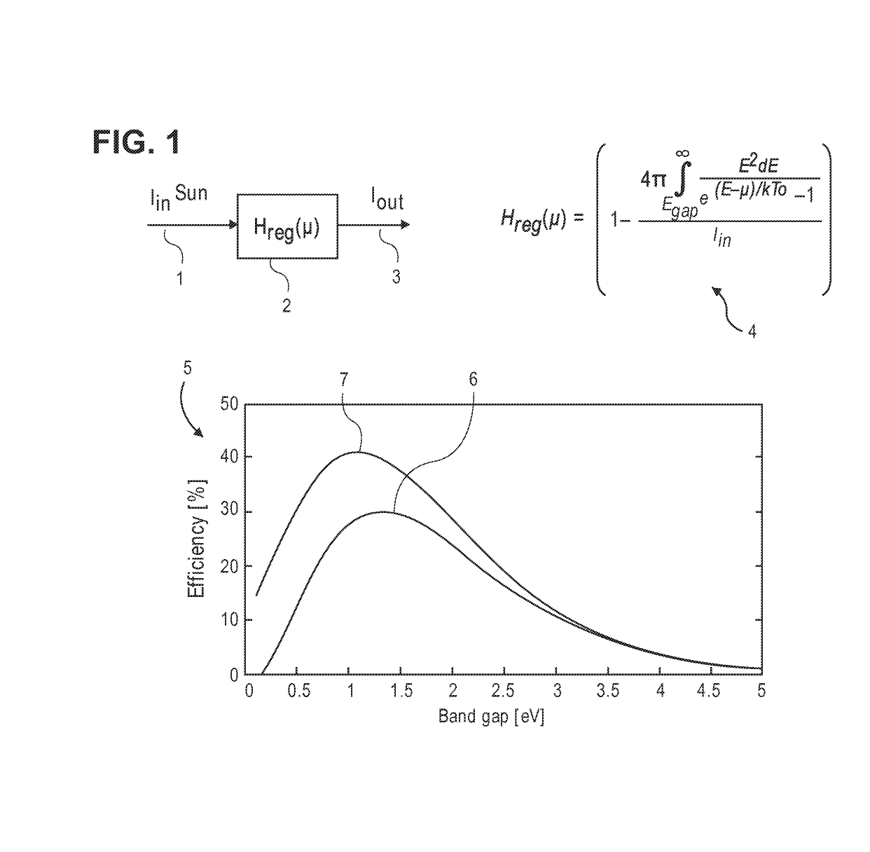

In embodiments of the present invention, the workings of a solar cell, using the detailed balance formalism can be encompassed into the system block diagram 1, 2, and 3 of FIG. 1, with the input photon flux current 1 from the sun entering a solar cell 2, and exiting as blackbody radiation 3 as a function of the transfer function 4 of the system. In particular, the transfer function 4 of a PVS follows Eq. (9). The efficiency of a PVS using the detailed balance formalism can be calculated using this transfer function 4, and displays the maximal efficiency 5 per bandgap of a single junction PVS, assuming no losses in the PVS material, that all the recombination of electron-hole pairs is radiative, and that the impedance of the incoming photon flux 1 is perfectly matched to the PVS material's index (n=1). Assuming no concentration (C=1), the maximum of this calculated efficiency curve 6 is at ˜30% for a bandgap of ˜1.3 eV. Adding concentration to the system can increase the efficiency (efficiency curve 7) to near the Ultimate Efficiency (44%), and can achieve a maximum of ˜41% for a bandgap of ˜1.1 eV.

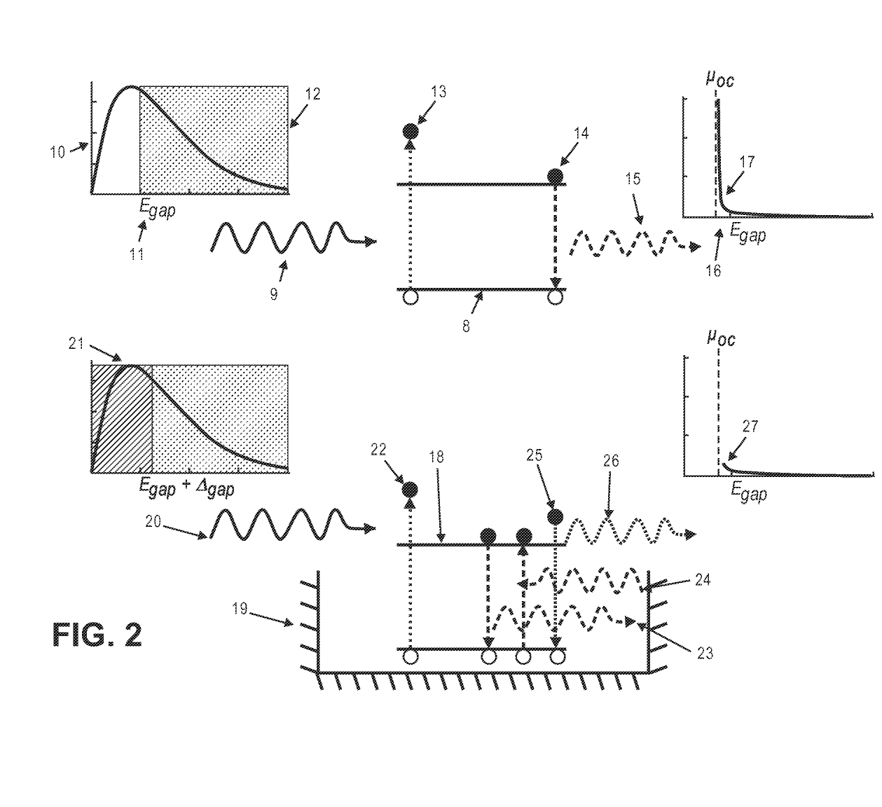

Referring to FIG. 2, for a traditional PVS arrangement, as simplified by a two-level system 8, incoming photon flux 9 can be considered to yield a cutoff spectrum 12 of incoming photons at the bandgap, E_{gap} 11, as described in Eq. (1), with the PVS absorbing all photons 9 above this threshold E_{gap} 11. This flux of incoming photons 9 is absorbed by the PVS and can create an electron-hole pair 13, with excess energy lost to thermalization within the conduction (or LUMO) bands. Once at the bandgap 14, the electrons can radiatively recombine with holes, thus producing a photon 15 at the bandgap, with an energy equivalent to the bandgap energy, minus the chemical potential 16. This form of band-to-band recombination produces a spectrum that is different from the regular blackbody radiation 10, with a sharp, one-sided peak from the chemical potential, μ_{oc}, and up 17.

In an embodiment of the present invention, a PVS system 18 may be surrounded by selective reflectors 19, such that the incoming photon flux 20 is cutoff not at the bandgap 11, but at a slightly increased energy (frequency), corresponding to E_{gap}+Δ_{gap} 21. This selective reflector 19 modifies the incoming photons 20 such that only photons from E_{gap}+Δ_{gap} and up enter the PVS 18, creating electron-hole pairs 22. Recombining electrons will produce photons 23 with the same properties as the regular PVS 8, however, due to the selective reflector 19, these photons are reflected back into the PVS 24 where they can be re-absorbed. This re-absorption process forces a higher energy population of electrons to be formed at an elevated Fermi level 25, as similar to the electronic effect of degenerate doping (Burstein-Moss effect), and therefore the only emission channel the PVS has to balance the photon flux, assuming that spontaneous emission is the primary emission process, is to emit higher energy photons 26. This new emission profile effectively is cutoff at the selective reflector edge 21, such that the sharp emission profile of the band-to-band emission 17 is decreased 27. This process is previously described in the “Summary” section, with an expected increase in open-circuit voltage due to the feedback of the photons into the PVS. The recapture of bandgap emitted photons 24 between the PVS 18 and the selective reflector 19 is the invention disclosed.

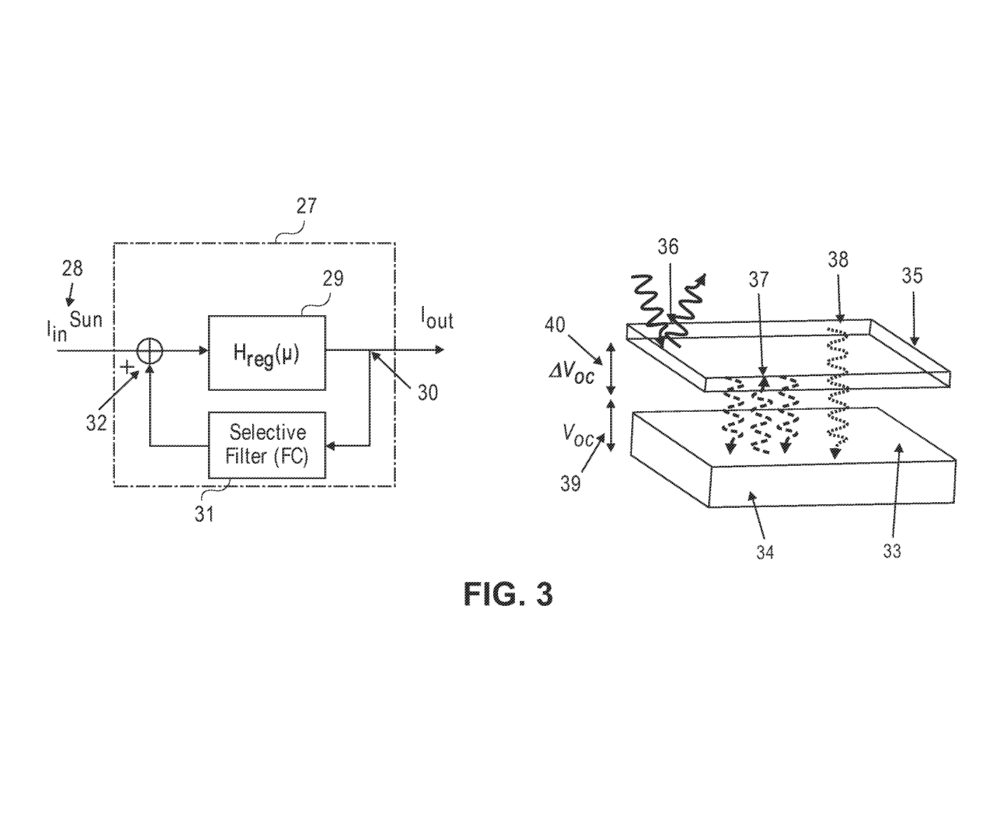

A system block diagram/schematic of an embodiment of the invention is described in FIG. 3. The system 27 accepts the same solar spectrum 28, and uses the same physical processes to create power, using the transfer function methodology 29. However, the output flux Iₒᵤₜ from the PVS 30 is sent through a feedback loop 30, consisting of a selective filter/reflector 31, and added 32 to the input current Iᵢₙ as a positive feedback signal 32. Schematically, the device can be generalized, but not limited to, a PVS material 33 that is reflective (selective, or broadband) on all sides 34, with a selective reflector material 35 between the incoming solar spectrum and the PVS. The selective reflector 35 blocks all lower energy photons 36, and allows higher energy photons 38 to be absorbed by the PVS. The re-emitted photons 37 are captured in the selective reflector 35, such that the overall open-circuit voltage of the PVS as following the traditional detailed balance formalism 39 is increased due to the capacitive feedback 40 of the selective reflector 35. The PVS material 33 is generalized to include bulk, thin-film, structured (micro-, nano-, etc.), materials, as well as generalized to include both inorganic and organic/polymeric materials. The physical region of the selective reflector 35 is material dependant, with the distance between the PVS 33 and the selective reflector 35 only shown here as separated by a large gap for schematic purposes.

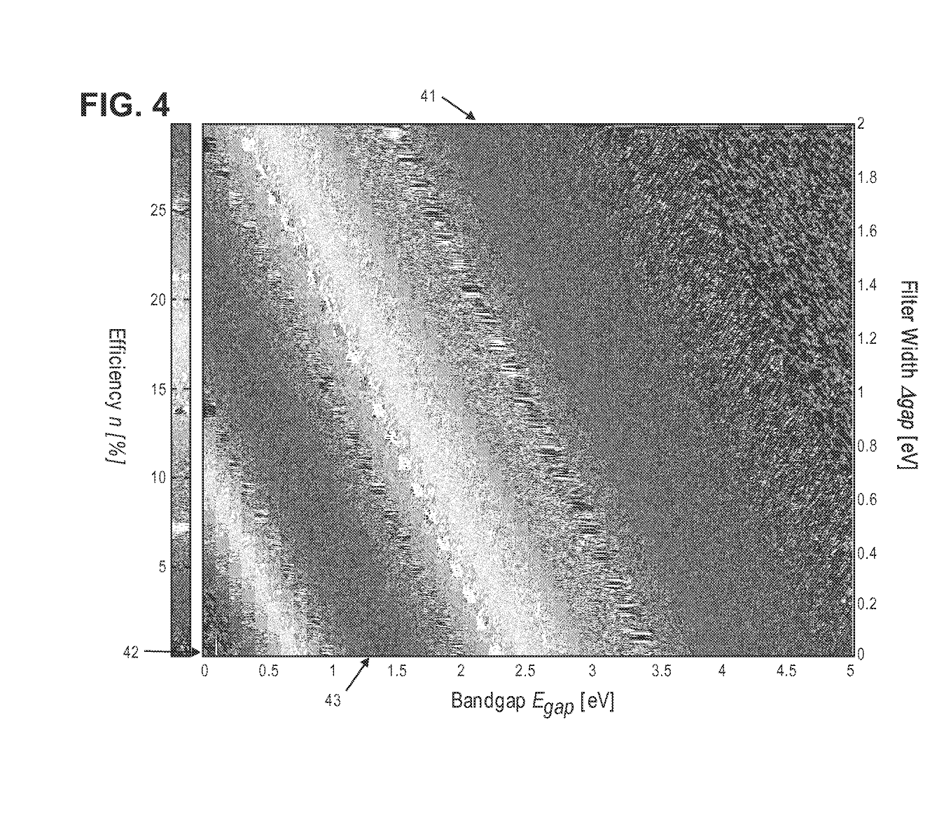

The maximal theoretical efficiency increase using this device concept, using the thermodynamic analysis method as described in the “Summary” section above, can be found by maximizing the current-voltage product, as normalized by the incident solar spectrum power, and adding the feedback mechanism of the selective reflector method. This calculation provides an efficiency per bandgap curve for each value of the width of the selective reflector, Δ_{gap}, in a 2D plot 41 in FIG. 4. The graph of FIG. 4 was plotted at no concentration (C=1). This curve includes the traditional detailed balance limit 6, such that with no selective reflector (Δ_{gap}=0) 42, the ˜30% maximum at ˜1.3 eV bandgap is found 43. However, this curve shows the relationship between the reflector width, and the shifting of maximal efficiency towards lower bandgaps (to the left). Essentially, the device shifts the optimal bandgap such that the addition of the original PVS material's effective bandgap (E_{gap}) and the width of the selective reflector (Δ_{gap}) combine to match the regular detailed balance limit at ˜1.3 eV 43 with no feedback added.

This result would appear to conflict with the 2^{nd} law of thermodynamics, since it produces voltages that are higher than the bandgap; however, due to the feedback, the effective bandgap is what is changed, and the formalism used is derived only from thermodynamic principles. The basic assumptions of the derivation are only the detailed balance of photons, including feedback, as well as the assumption that the PVS acts as a two level system (or, rather, a two band system).

An embodiment of the invention may be illustrated in FIG. 3, with a single junction PVS material 33, covered by a selective reflector 35. In this embodiment, an existing PVS 33 can consist of a planar or bi-facial, PVS, with the backside and edges covered with complete, frequency-dependent reflectors 34, and only the face with a component normal to the incidence of the sunlight featuring the selective reflector 35. In another embodiment of the device, the backside of the PVS 33 can contain a selective reflector as well. However, due to symmetry, there is no loss in generality of describing the uni-facial geometry only.

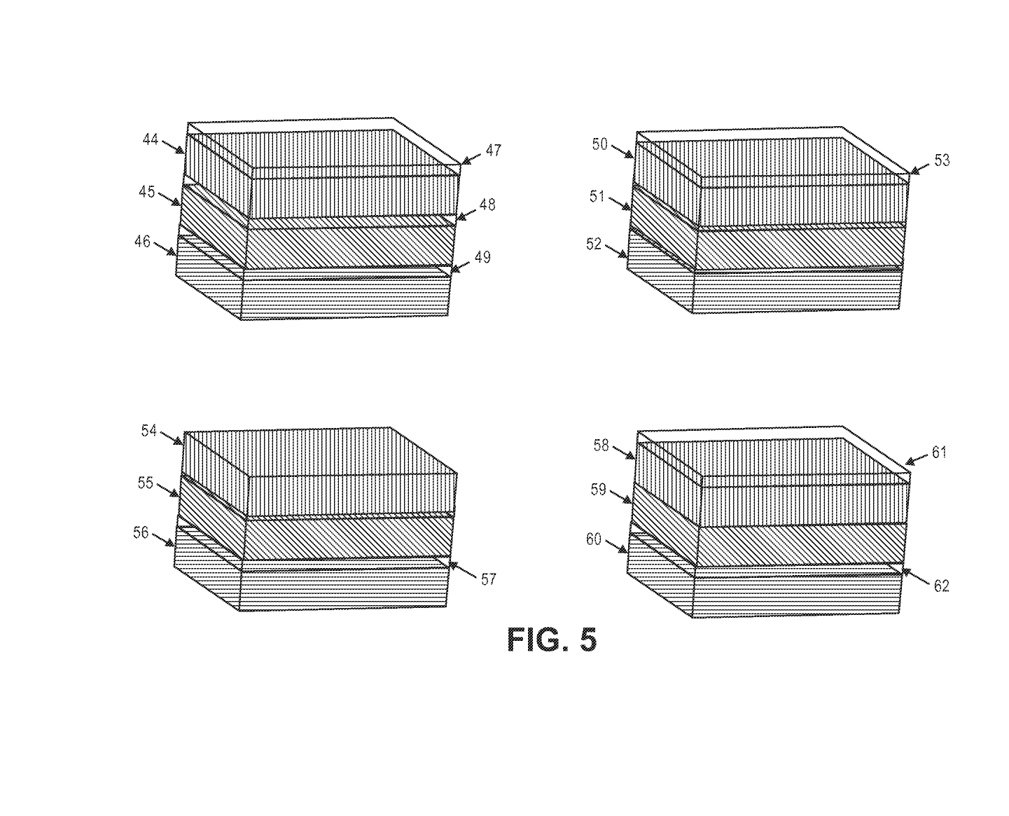

In another embodiment of the device, the selective reflectors are integrated into a multi-junction PVS design, as in FIG. 5. For generality, FIG. 5 describes a 3 layer multi-junction system; however, no generality is lost by describing a PVS with n layers, or 2 layers, with one layer being included in the embodiment of the device above.

For this embodiment, for a three material system, with bandgaps ranging from large 44, medium 45 and small 46, with no loss of generality, three selective reflectors 47, 48, 49 can be added to each layer 44, 45, 46, respectively, such that the initial surface 47 is first selectively filtered, followed by a middle layer 48, and finally by the bottom layer 49. In this embodiment, each layer 44, 45, 46 is both optimized for the solar spectrum, as is traditionally calculated using the modified detailed balance for a tandem cell; however, they are furthermore optimized by inserting the feedback selective reflectors 47, 48, 49, thereby capturing the essential re-emission within each layer. This further optimization using the feedback can improve the current matching difficulties of stacked multi-junction cells, however adds additional material matching problems by introducing the selective reflectors between each layer.

In another embodiment of this device, a three layer high 50, medium 51 and low 52 bandgap stack of materials may only be covered by a selective reflector 53 on the top layer 50. This selective reflector 53 may act as an optimizer for the high bandgap material only, filtering out low energy photons for the underlying layers as well. This embodiment may simplify the material matching difficulties, as only single materials needs to be matched, with the external layer open to air, or other materials such as anti-reflection coatings.

Another embodiment may include the same layer structure of a high 54, medium 55 and low 56 bandgap stack of materials, with a selective reflector 57 placed only for the lowest material 56. This embodiment is preferable for only needing to match 2 material systems (between the lowest 56 and next higher 55 materials), as well as utilizing the lowest energy photons re-emitted from the lowest bandgap material 56, which cannot be utilized by any other material without feedback, and would thus only produce losses.

Another embodiment includes selective reflectors 61, 62 for the high 58 and low 60 bandgap materials, respectively, and not for any internal layers, generalized by a single bandgap middle level here 59. Here, both the top, and bottom two layers 58, 60 need to be material matched to the upper 61 and lowest 62 selective reflectors, respectively. This embodiment may be selected since it captures the optimization capabilities of the previous two embodiments, while limiting the number of materials that need to be matched. Furthermore, it emphasizes that the primary advantages to be had are from the upper and lowest layers of a multi-junction PVS, using an embodiment of the invention, since internal layers may not lose the re-emitted light completely, as it is re-absorbed into the underlying layers even without selective reflectors.

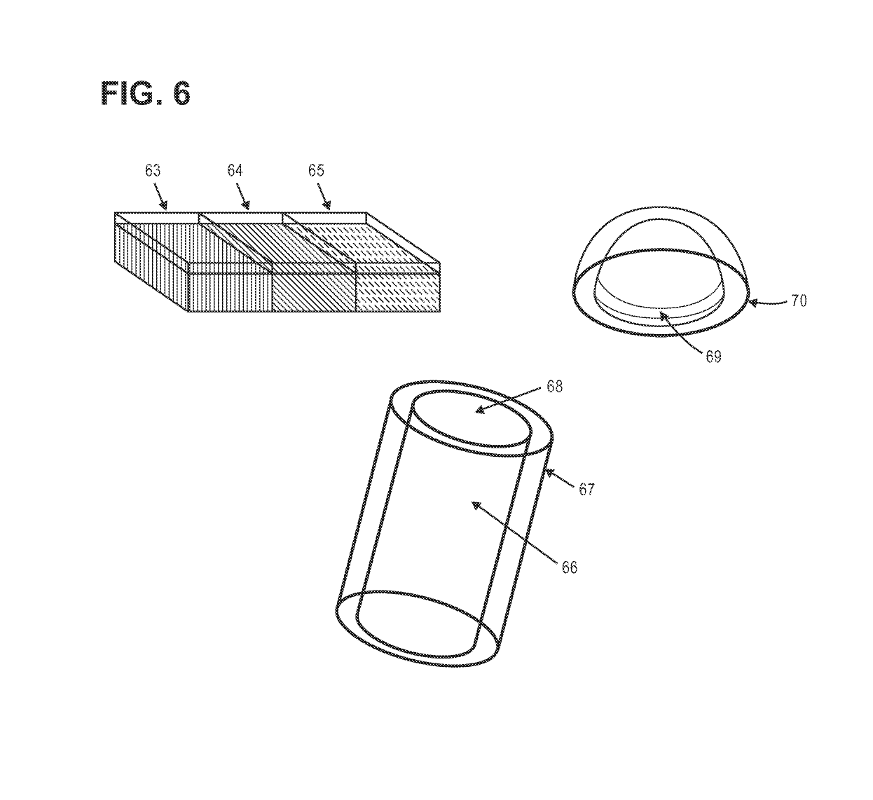

Another embodiment of this device uses a non-stacked multi-junction PVS, generalized as a three layer planar cell as shown in FIG. 6. In this embodiment, each layer of the multi-junction may have its own selective reflector, with low 63, middle 64 and high 65 bandgap PVS placed in a horizontal geometry—as opposed to the stacked geometry of FIG. 5. In this embodiment, the material matching layers between the PVS and the selective reflector are attenuated: however, the additional difficulty of modifying the solar spectrum so that it is split into the adjacent PVS systems occurs. In this embodiment, different selective reflectors can be used for each sub-PVS layer, or overlapping reflectors can be used, since the selective reflectance of the lower bandgaps also correspond to those of the higher bandgaps.

In another embodiment of the device, the planar structure of most PVS systems can be changed, to include more complex geometries. As examples of these, but not limited to them, a cylindrical PVS 66 can be cylindrically covered by the selective reflector 67, either with or without the edges 68. In additional example, a hemispherical (or spherical) PVS 69 can also be coated with a selective reflector 70. In both of these examples of this embodiment, the advantages gained by using a non-planar system are retained when adding the reflectors. Therefore, the device described here can always be added to an existing geometry to improve the efficiency.

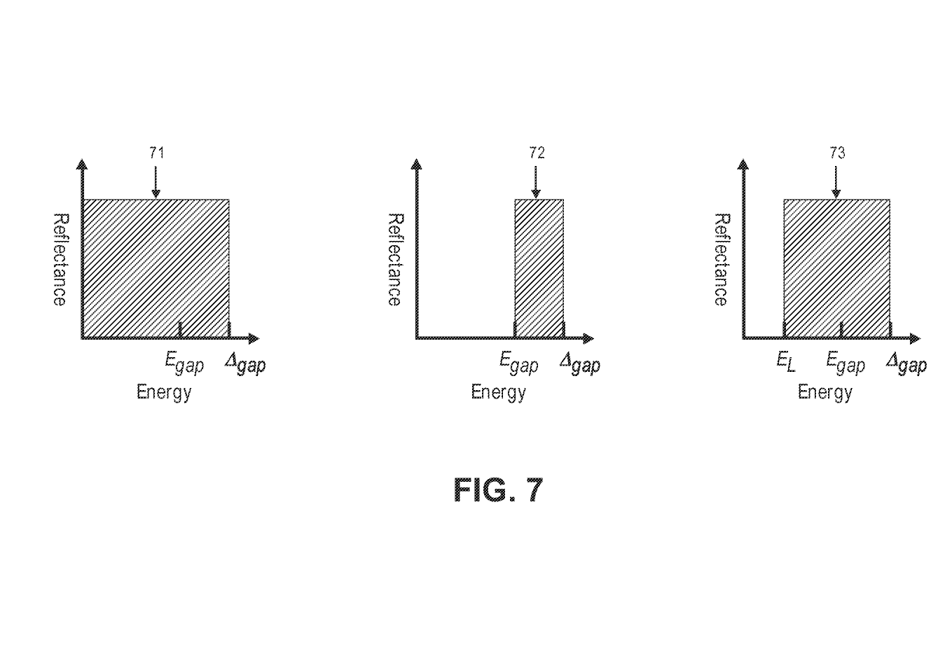

In various embodiments of the device, the reflective properties of the reflectors can be generalized in FIG. 7. The selective reflector can be chosen to be either a HPF- or a NF-like reflector, depending on the material requirements of the system. The most basic form of the selective reflector is a HPF-reflector 71, whereupon all the photons below the threshold of E_{gap}+Δ_{gap} are blocked. In this embodiment, an advantage is gained by both blocking the re-emission of band-to-band recombination, which is an advantage described by embodiments of this invention, but also blocking the lower energy photons, that are absorbed within the conduction band of the PVS and produce excess heat due to thermalization. This form of selective reflector may be useful for the single junction PVS embodiment 33, or on the lowest level 56 of a multi-junction stack, or in a horizontally stacked multi-junction PVS 63, 64, 65, since the selective reflector would otherwise block all light to the underlying layers.

Another form of selective reflector 72 blocks the band-to-band re-emission from the bandgap up to the edge of the filter width, optimized such that the majority of the re-emission is reflected. In this variation of NF-reflector, only the critical frequencies must be reflected back to the PVS, simplifying the bandwidth requirements of the NF-reflector. For example, a Bragg reflector can be easily matched to such a small bandwidth requirement, as can an interference-based reflector. Furthermore, this form of reflector is best suited for the multi-junction stacked PVS, since underlying layers are not negatively affected by the placement of the reflector 72.

Another variation is the reflector 73 which is a generalized combination of the NF and HPFs, where the NF-reflector 73 is centered around the bandgap, up to Δ_{gap}, and down to a lower threshold energy, E_{L}. For the case that E_{L}=0, this reverts to the HPF-reflector case.

FIG. 7 also describes the selective reflectors 71, 72, and 73 in terms of wavelength along the horizontal axis. Thus, selective reflectors 74, 75, and 76 are a short-pass filter, a NF-reflector, and a combination of the NF and short-pass filter, respectively.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

We claim:

1. A photovoltaic system comprising:
a photovoltaic cell; and
a selective reflector coupled to the photovoltaic cell in a feedback path.

2. The photovoltaic system of claim 1, wherein the selective reflector is selected from a group consisting of a photonic crystal, a dielectric mirror, a bragg reflectors, a distributed bragg reflector (DBR), an interference filter, a mirror, a metamaterials reflectors, a frequency tuned diffractive grating, a plasmonic reflector, and transformation optics.

3. A method of improving the efficiency of lower than optimal bandgap photovoltaic systems using a feedback design, coupled with a selective reflector.

4. The method of claim 3, wherein the photovoltaic is in a single bandgap design structure.

5. The method of claim 4, wherein the design of the photovoltaic system is planar.

6. The method of claim 4, wherein the design of the photovoltaic is non-planar, including cylindrical and spherical.

7. The method of claim 4, wherein the design of the photovoltaic is structured, including macro-, micro- or nano-structuring.

8. The method of claim 4, wherein the material of the photovoltaic is inorganic.

9. The method of claim 4, wherein the material of the photovoltaic is organic/polymeric.

10. The method of claim 4, wherein the photovoltaic system is illuminated by solar radiation

11. The method of claim 10, wherein the solar illumination is concentrated.

12. A method of improving the efficiency of multi-junction photovoltaics using a feedback design.

13. The method of claim 12, wherein the selective reflector is designed for the top layer in a stacked design.

14. The method of claim 12, wherein the selective reflector is designed for the bottom layer in a stacked design.

15. The method of claim 12, wherein the selective reflector is designed for any middle layer in a stacked design, generalized for any system with 3 or more layers.

16. The method of claim 12, wherein the selective reflector is designed for the top and bottom layers in a stacked design.

17. The method of claim 12, wherein the selective reflector is designed for all the layers in a stacked design.

18. The method of claim 12, wherein the selective reflector is designed for all the layers in a non-stacked design, including any horizontal configuration of photovoltaic materials.

19. A feedback design based on a selective reflector that reflects the emitted photon flux from the photovoltaic system, up to a defined filter width (Δ_{gap}).

20. The feedback design of claim 19, wherein the reflector reflects all photons with energies less than the bandgap plus the filter width, effectively acting as a high pass filter.

21. The feedback design of claim 19, wherein the reflector reflects all photons with energies between the bandgap and the filter width, effectively acting as a notch filter.

22. The feedback design of claim 19, wherein the reflector reflects ail photons with energies less than the bandgap plus the filter width, and more than a given lower energy threshold (E_{L}), effectively acting as a band stop filter.

23. The feedback design of claim 19, wherein the selective reflector is on a single face of the photovoltaic system.

24. The feedback design of claim 19, wherein the selective reflector is on up to all external sides of the photovoltaic system.

25. A method of reflecting photons back into the photovoltaic material using selective reflectors selected from the group consisting of a photonic crystal, a dielectric mirror, a bragg reflector, a distributed bragg reflector (DBR), an interference filter, a mirror, a metamaterials reflectors, a frequency tuned diffractive grating, a plasmonic reflector, and transformation optics.

26. The method of claim 25, wherein the reflector follows the properties of claim 17.

27. The method of claim 25, wherein the reflector consists of a combination of technologies.

28. The method of claims 25, wherein the edges of the reflection/filtering are not step functions. This includes all gradient reflectors/filters of any function of energy.
